(19) United States
(12) Patent Application Publication
(10) Pub. No.: US 2017/0345542 A1
(43) Pub. Date: Nov. 30, 2017

(54) Gas Chromatograph And Multiport Valve Unit For A Gas Chromatograph

(71) Applicant: Siemens Aktiengesellschaft, Muenchen (DE)

(72) Inventors: Josef RICHTER, Karlsruhe (DE); Piotr STRAUCH, Rülzheim (DE)

(21) Appl. No.: 15/536,203

(22) PCT Filed: Dec. 15, 2014
(86) PCT No.: PCT/RU2014/000946

§ 371 Date: Jun. 15, 2017

(51) Int. Cl. H01F 27/10; H01F 27/28; H01P 5/10; H05K 1/16

(52) U.S. Cl. CPC H01F 27/10; H05K 1/165; H01F 27/2804; H01P 5/10; H05K 2201/064

(57) ABSTRACT

A fluid-cooled balun transformer that includes a substrate plate with a first and an opposite second face, a first and a second conductive element arranged on the first and the second face, respectively, wherein a first and a second signal port electrically is connected to the first and the second conductive element, respectively, and a cooling module, where the second conductive element is transformingly coupled to the first conductive element and electrically isolated therefrom, the cooling module includes a first tubular member, the first tubular member has a fluid inlet to receive a coolant fluid into the first tubular member, a flow channel to conduct a flow of coolant fluid within the first tubular member and a fluid outlet to release the coolant fluid from the first tubular member, and where the flow channel of the first tubular member is arranged in thermal contact with the first conductive element.

### CROSS-REFERENCE TO RELATED APPLICATIONS

This is a U.S. national stage of application No. PCT/RU2014/000946 filed 15 Dec. 2014.

### BACKGROUND OF THE INVENTION

### 1. Field of the Invention

The present invention relates to transformers capable of matching a single-ended output to a balanced input, i.e., balun transformers and, more particularly, to cooling techniques of balun transformers for radio-frequency (RF) power applications.

### 2. Description of the Related Art

High power radio frequency (RF) sources are used in many applications, such as for broadcast, communications, radars, or healthcare applications. One of the important elements of RF sources and, more particularly high power RF sources, is a final power amplifier. Solid state transistor based power amplifiers have smaller dimensions, better reliability, and higher efficiency compared to conventional RF power sources based on vacuum tubes like klystrons, tetrodes, and inductive output tubes.

Presently, the upper limit power capability of single RF power transistors is in a range of 1-1.5 k (kilowatts). In cases where output power requirements, i.e., the power demand, exceed power that a single transistor can deliver, a plurality of transistors may be combined to collectively meet the power demand. A convenient and useful method of combining or coupling two transistors is a technique known as the ‘push-pull’ schematic. In the ‘push-pull’ scheme, the drive is shared between a first transistor driving current through the load in one direction and a second transistor driving current through the load in the opposite direction. However, the ‘push-pull’ circuit is a balanced system in that it produces an output signal that is symmetrical with respect to the common ground potential of the coupled transistors, whereas typically a single-ended (that is ground referenced) output signal is required. A solution to this problem is to provide a transformer between the output of the ‘push-pull’ pair and the load. This transformer is able to couple the balanced output to the single-ended load. Such a transformer is that referred to in the art as a ‘balun’ (balanced to unbalanced transformation).

Many forms of a balun, including transmission line forms, are known in the art. Presently, one of the most promising designs of the balun transformer, from the viewpoint of manufacturing and assembling, is Printed Circuit Board (PCB) based planar transformer. The PCB balun transformers, as depicted in, for example , U.S. Pat. No. 5,061,910 titled ‘Balun Transformers’, are being widely used in the art. However, these balun transformers, and particularly the PCB balun transformers, are disadvantaged by an intriguing problem of overheating, primarily overheating of primary and secondary conductive elements, i.e., conductive tracts of the PCB acting as primary and secondary windings in the PCB balun transformers and overheating of other embedded electronics present in the conductive tracts, such as capacitors if any connected in the conductive tracts, of the PCB balun transformers.

Presently, in some of the PCB balun transformers the problem of overheating is addressed with increasing heat dissipation by using substrate (PCB substrate) material with high thermal conductivity. Another conventional solution is the use of a pre-matching circuit to reduce the transformation ratio for the transformer and therefore reduce current flow in the transformer. Yet another conventional solution is to use air-cooled fins on the top of the transformer. However, none of these techniques effectively address the problem of overheating, and more particularly for RF power applications that operate at RF power levels higher than 1.2 kW.

### SUMMARY OF THE INVENTION

In view of the foregoing, it is an object of the present technique to provide a balanced to unbalanced (balun) transformer with an efficient cooling system. Furthermore, it is desirable that the balun transformer with the cooling system of the present technique is compact, easy to integrate into the balun transformer, and simple.

These and other objects and advantages are achieved in accordance with the invention by a fluid-cooled balun transformer that includes a substrate plate, a first and a second conductive element, a first and a second signal port, and a cooling module. The substrate plate has a first face and a second face. The first face and the second face are opposite to each other. The first conductive element is arranged on the first face of the substrate plate. The second conductive element is arranged on the second face of the substrate plate. The second conductive element is transformingly coupled to the first conductive element and electrically isolated therefrom. The first signal port is electrically connected to the first conductive element. The second signal port is electrically connected to the second conductive element.

The cooling module includes a first tubular member. The first tubular member has a fluid inlet to receive a coolant fluid into the first tubular member, a flow channel to conduct a flow of coolant fluid within the first tubular member and a fluid outlet to release the coolant fluid from the first tubular member. The flow channel of the first tubular member is arranged in thermal contact with the first conductive element.

When the fluid-cooled balun transformer is in use, a suitable coolant fluid is introduced into the fluid inlet of the first tubular member. The suitable coolant fluid then flows through the flow channel of the first tubular member to the fluid outlet of the first tubular member and exits through the fluid outlet of the first tubular member. The flow channel is in thermal contact with the first conductive element. As a result, heat from the first conductive element transmits to the flow channel of the first tubular member and is thus received by the coolant fluid flowing in the flow channel of the first tubular member and is subsequently carried, along with the coolant fluid, off the fluid-cooled balun transformer through the fluid outlet of the first tubular member. The coolant fluid may be a suitable coolant liquid. Fluid cooling, particularly liquid cooling, is more efficient than cooling by only dissipation of heat. This active cooling technique provides an efficient way of cooling in the balun transformer of the present invention. Moreover, the cooling method and the construction is simple, easy to integrate and capable of fabrication in a compact configuration.

In an embodiment of the fluid-cooled balun transformer, at least a part of the first conductive element is printed on the first face of the substrate plate. This provides an advantageous embodiment of a printed circuit board (PCB) based balun transformer of the present embodiment. This also helps in compact design of the fluid-cooled balun transformer.

In another embodiment of the fluid-cooled balun transformer, at least a part of the second conductive element is printed on the second face of the substrate plate. This provides an advantageous embodiment of a PCB based balun transformer of the present embodiment. This also helps in compact configuration of the fluid-cooled balun transformer.

In another embodiment of the fluid-cooled balun transformer, the flow channel of the first tubular member is arranged in thermal contact with the first conductive element by direct physical contact of the first tubular member and the first conductive element. This ensures good thermal contact between the first conductive element and the flow channel of the first tubular member through a wall or surface of the first tubular member.

In another embodiment of the fluid-cooled balun transformer, the first conductive element includes a ground point for grounding the first conductive element. The fluid inlet of the first tubular member or the fluid outlet of the first tubular member or both (the fluid inlet and the fluid outlet) of the first tubular member are positioned in the vicinity of (proximate to) the ground point of the first conductive element. This placement of the fluid inlet and/or fluid outlet of the first tubular member reduces the effect of existence of the first tubular member, and the coolant fluid flowing in the first tubular member during use of the fluid-cooled balun transformer, on the top of the first conductive element with respect to RF power flow through the fluid-cooled balun transformer. Moreover, in case the grounding point is in direct connection to ground, the fluid inlet and/or fluid outlet of the first tubular member may be connected to an external fluid connection with metal pipes instead of plastic pipes.

In another embodiment of the fluid-cooled balun transformer, the flow channel of the first tubular member is configured to conduct the flow of the coolant fluid turbulently. Turbulent flow of the fluid is achieved by ensuring that the flow channel has turbulence creating structures in the flow path of the fluid coolant, such as protrusions from an inner surface of a wall of the first tubular member into the flow channel of the first tubular member. Turbulent flow of the fluid ensures that a greater part of the volume of the flowing coolant fluid is used optimally to receive the heat from the flow channel of the first tubular member. As a result, the efficiency of cooling achieved is enhanced by a given amount of coolant fluid flowing at a given rate through the flow channel of the first tubular member.

In another embodiment of the fluid-cooled balun transformer, the shape of the flow channel of the first tubular member is different from the shape of the first tubular member. This ensures that the flow channel inside the first tubular member is shaped so as to increase the thermal contact between the first conductive element and the flow channel of the first tubular member.

In another embodiment of the fluid-cooled balun transformer, the first signal port is a balanced signal port and the second signal port is a single-ended signal port. Thus, when the fluid-cooled balun transformer is in use, the first conductive element functions as a primary winding of the fluid-cooled balun transformer. Therefore, cooling is provided to the primary winding.

In another embodiment of the fluid-cooled balun transformer, the first signal port is a single-ended signal port and the second signal port is a balanced signal port. Thus, when the fluid-cooled balun transformer is in use, the first conductive element functions as secondary winding of the fluid-cooled balun transformer. Therefore, cooling is provided to the secondary winding.

In another embodiment of the fluid-cooled balun transformer, the cooling module includes a second tubular member. The second tubular member has a fluid inlet configured to receive a coolant fluid into the second tubular member, a flow channel configured to conduct a flow of coolant fluid within the second tubular member and a fluid outlet configured to release the coolant fluid from the second tubular member. The flow channel of the second tubular member is arranged in thermal contact with the second conductive element. When the fluid-cooled balun transformer is in use, a suitable coolant fluid is introduced into the fluid inlet of the second tubular member. The suitable coolant fluid then flows through the flow channel of the second tubular member to the fluid outlet of the second tubular member and exits through the fluid outlet of the second tubular member. The flow channel is in thermal contact with the second conductive element. As a result, heat from the second conductive element transmits to the flow channel of the second tubular member and is thus received by the coolant fluid flowing in the flow channel of the second tubular member and is carried off the fluid-cooled balun transformer through the fluid outlet of the second tubular member. Thus, both first and the second conductive elements are cooled simultaneously.

In another embodiment of the fluid-cooled balun transformer, the flow channel of the second tubular member is arranged in thermal contact with the second conductive element by direct physical contact of the second tubular member with the second conductive element. This ensures good thermal contact between the second conductive element and the flow channel of the second tubular member through a wall or surface of the second tubular member.

In another embodiment of the fluid-cooled balun transformer, the second conductive element includes a ground point for grounding the second conductive element. The fluid inlet of the second tubular member or the fluid outlet of the second tubular member or both (the fluid inlet and the fluid outlet) of the second tubular member are positioned in the vicinity of (proximate to)the ground point of the second conductive element. This placement of the fluid inlet and/or fluid outlet of the second tubular member reduces the effect of existence of the second tubular member, and the coolant fluid in the second tubular member during use of the fluid-cooled balun transformer, on the top of the second conductive element with respect to RF power flow through the fluid-cooled balun transformer. Moreover, in case the grounding point is in direct connection to ground, the fluid inlet and/or fluid outlet of the second tubular member may be connected to a fluid loop with metal pipes instead of plastic pipes.

In another embodiment of the fluid-cooled balun transformer, the flow channel of the second tubular member is configured to conduct the flow of the coolant fluid turbulently. Turbulent flow of the fluid is achieved by ensuring that the flow channel of the second tubular member has turbulence creating structures in the flow path of the fluid coolant, such as protrusions from an inner surface of a wall of the second tubular member into the flow channel of the second tubular member. Turbulent flow of the fluid ensures that a greater part of the volume of the flowing coolant fluid is used optimally to receive the heat from the flow channel of the second tubular member. This enhances the efficiency of cooling achieved by a given amount of coolant fluid flowing at a given rate through the flow channel of the second tubular member.

In another embodiment of the fluid-cooled balun transformer, the shape of the flow channel of the second tubular member is different from the shape of the second tubular member. This ensures that the flow channel inside the second tubular member is shaped so as to increase the thermal contact between the second conductive element and the flow channel of the second tubular member.

In another embodiment of the fluid-cooled balun transformer, the flow channel of the first tubular member is fluidly connected to the flow channel of the second tubular member.Thus, the same coolant fluid can be circulated in the first and the second tubular members making the cooling module simple and compact.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

The present technique is further described hereinafter with reference to illustrated embodiments shown in the accompanying drawing, in which:

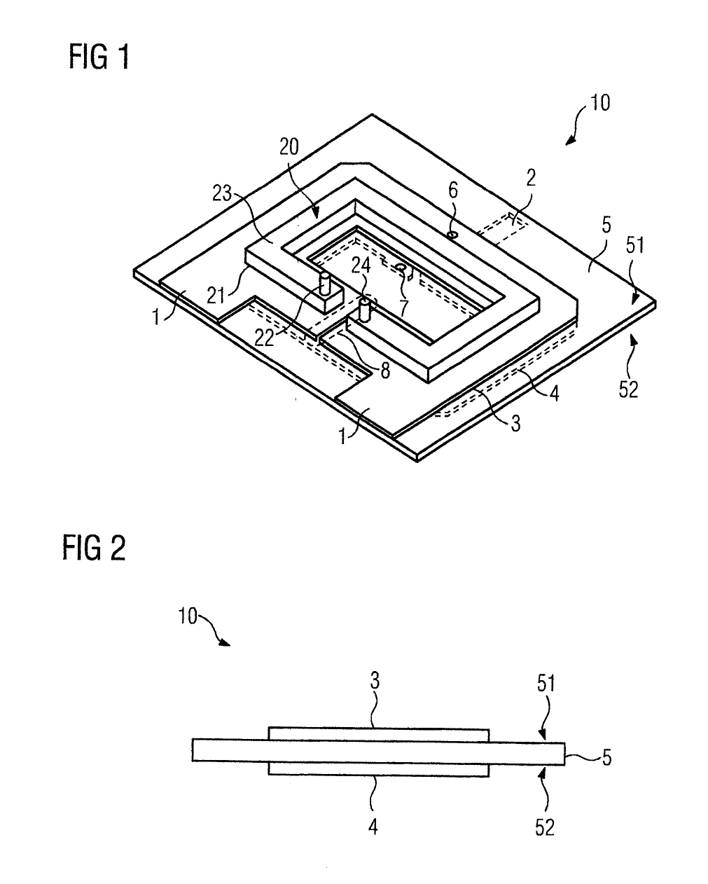

FIG. 1 schematically illustrates an exemplary embodiment of a fluid-cooled balun transformer in accordance with the invention;

FIG. 2 schematically illustrates parts of an exemplary embodiment of the fluid-cooled balun transformer viewed from a side without depicting cooling of the fluid-cooled balun transformer in accordance with the invention;

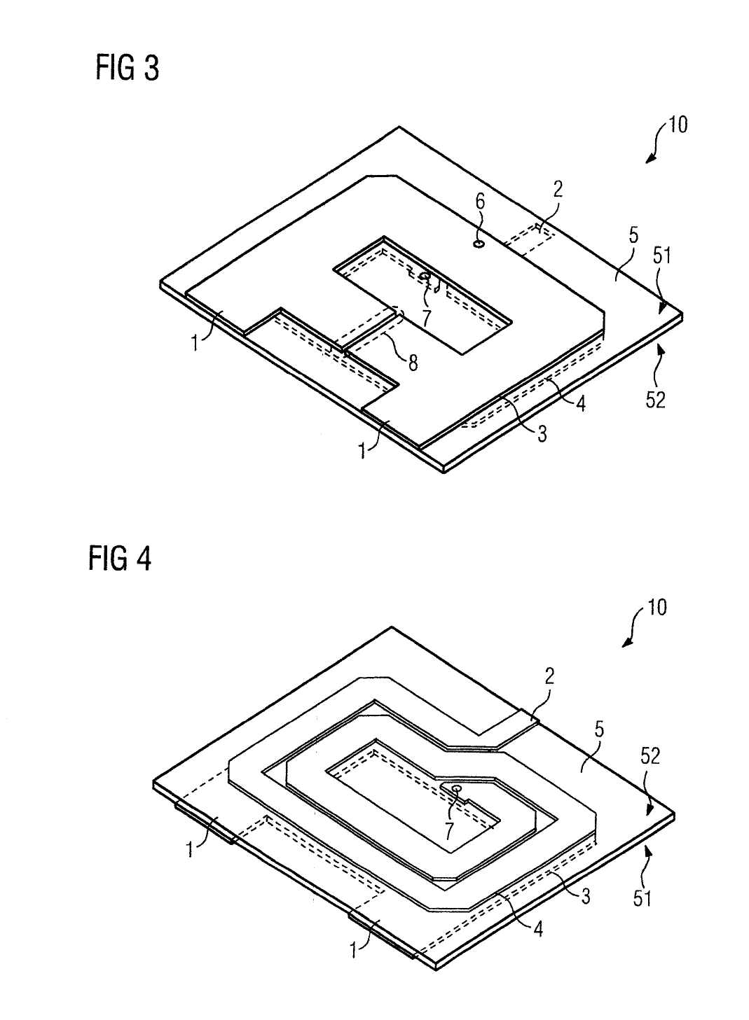

FIG. 3 schematically illustrates the exemplary embodiment of fluid-cooled balun transformer of FIG. 2 viewed from a top side;

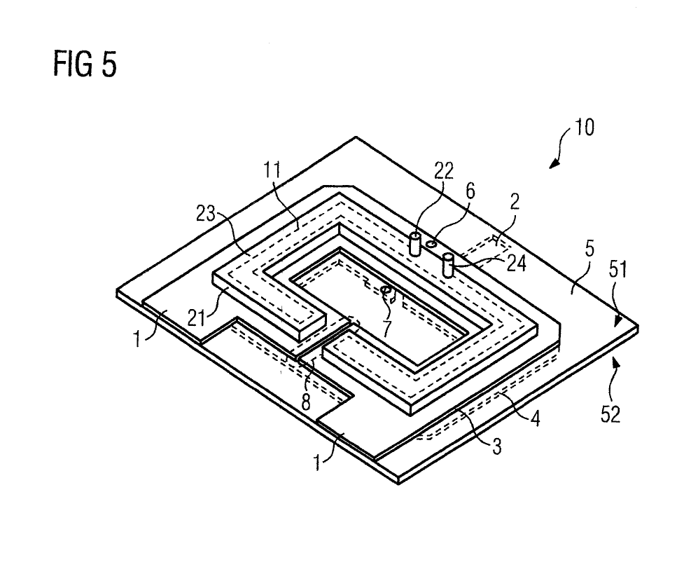

FIG. 4 schematically illustrates the exemplary embodiment of fluid-cooled balun transformer of FIGS. 2 and 3 viewed from a bottom side opposite to the top side of FIG. 3, and

FIG. 5 schematically illustrates another exemplary embodiment of the fluid-cooled balun transformer, in accordance with embodiments of the present invention.

### DETAILED DESCRIPTION OF THE EXEMPLARY EMBODIMENTS

Hereinafter, above-mentioned and other features of the present technique are described in details. Various embodiments are described with reference to the drawing, wherein like reference numerals are used to refer to like elements throughout. In the following description, for purpose of explanation, numerous specific details are set forth in order to provide a thorough understanding of one or more embodiments. It may be noted that the illustrated embodiments are intended to explain, and not to limit the invention. It may be evident that such embodiments may be practiced without these specific details.

FIG. 1 schematically illustrates an exemplary embodiment of a fluid-cooled balun transformer 10, in accordance with the present invention. The fluid-cooled balun transformer 10 includes a substrate plate 5, a first conductive element 3, a second conductive element 4, a first signal port 1, a second signal port 2, and a cooling module 20.

FIG. 1 is explained further in combination with FIGS. 2, 3 and 4. FIGS. 2, 3 and 4 schematically illustrate some parts of an exemplary embodiment of the fluid-cooled balun transformer 10, without depicting the cooling module 20. FIG. 2 schematically illustrates some parts of the fluid-cooled balun transformer 10 from a side view. FIG. 3 schematically illustrates the fluid-cooled balun transformer 10 of FIG. 2 viewed from a top view. FIG. 4 schematically illustrates the fluid-cooled balun transformer 10 of FIGS. 2 and 3 viewed from a bottom view opposite to the top view of FIG. 3.

As depicted in FIG. 2, the fluid-cooled balun transformer 10 includes the substrate plate 5. The substrate plate 5 has a first face 51 and a second face 52. The first face 51 and the second face 52 are opposite to each other, i.e., first face 51 and the second face 52 are reverse sides of each other. In one embodiment, the substrate plate 5 has a planar structure, as depicted in FIG. 2, and first face 51 and the second face 52 are different faces of the two major faces of the plane, i.e., the two planes formed by the length and breadth of the planar structure without involving the faces that form the width of the planar structure. The substrate plate 5 is electrically non-conductive and may be formed of semiconductor or electrically insulating material, such as silicon, silicon dioxide, or aluminum oxide. The first conductive element 3 is arranged on the first face 51 of the substrate plate 5. The second conductive element 4 is arranged on the second face 52 of the substrate plate 5.

The first conductive element 3 and the second conductive element 4 are transformingly coupled to each other. The first conductive element 3 and second conductive element 4 are electrically isolated from each other. The term ‘conductive’ as used herein means conductive to RF (radio frequency) power or RF signals. It may be noted that in the present disclosure the term ‘transformatively coupled’ or similar phrases mean arranged such that energy between two or more circuits or conductors or conductive elements 3 and 4 are transferred through electromagnetic induction. Thus, when RF power or a signal is received by the first conductive element 3, it is conducted or propagated through the first conductive element 3 arranged on first face 51 of the substrate plate 5 and, by this propagation or flow of the RF power through the first conductive element 3, a current and corresponding power flow is electromagnetically induced in the other conductive element, i.e., second conductive element 4 placed on the other side, i.e., second face 52 of the substrate plate 5. Alternatively, when RF power or a signal is received by the second conductive element 4, and is conducted or propagated through the second conductive element 4 arranged on second face 52 of the substrate plate 5, then by this propagation or flow of the RF power through the second conductive element 4 a current and corresponding power flow is electromagnetically induced in the other conductive element, i.e., the first conductive element 3 placed on the other side, i.e., the first face 51 of the substrate plate 5. The first conductive element 3 and/or the second conductive element 4 are arranged on their corresponding faces, i.e., the first and the second face 51, 52 by either attaching conductive material on the substrate plate 5, such as by soldering, or by printing a conductive material on the surface of the substrate plate 5. The technique of printing conductive material on substrate plates, also called as wafers, is well known in the art of printed circuit boards and thus has not been explained herein in details for sake of brevity.

FIG. 3 and FIG. 4 depict a view of first face 51 and a view of second face 52, respectively. The fluid-cooled balun transformer 10 includes a first signal port 1 connected to the first conductive element 3 and thus RF power received by the first signal port 1 propagates or flows to the first conductive element 3, or vice versa any electromagnetically induced current in the first conductive element 3 propagates or flows to the first signal port 1 and is able to leave the fluid-cooled balun transformer 10 from the first signal port 1. Furthermore, the fluid-cooled balun transformer 10 includes a second signal port 2 connected to the second conductive element 4 and thus any electromagnetically induced current in the second conductive element 4 propagates or flows to the second signal port 2 and is able to leave the fluid-cooled balun transformer 10 from the second signal port 2, and vice versa any RF power received by the second signal port 2 propagates or flows to the second conductive element 4.

In one embodiment of the fluid-cooled balun transformer 10, the first signal port 1 is a balanced signal port and the second signal port 2 is a single-ended signal port, as depicted in FIGS. 3 and 4. Thus, when the fluid-cooled balun transformer 10 is used to match balanced input to single-ended output, the first conductive element 3 functions as a primary winding of the fluid-cooled balun transformer 10, and the second conductive element 4 functions as a secondary winding of the fluid-cooled balun transformer 10.

Alternatively, in another embodiment (not shown) of the fluid-cooled balun transformer 10, the first signal port 1 is a single-ended signal port and the second signal port 2 is a balanced signal port. Thus, the first conductive element 3 is capable of functioning as a secondary winding of the fluid-cooled balun transformer 10, and the second conductive element 4 capable of functioning as a primary winding of the fluid-cooled balun transformer 10.

The first conductive element 3 includes a ground point 6 that is connected to ground directly or via one or more capacitors.

Optionally, the second conductive element 4 includes a ground point 7 that is connected to the ground or may have no connections and left open. The area or region 8 on the first face 51, i.e., associated with the first conductive element 3 or the primary winding 3 can be used for capacitor placement to optimize transformer behavior of the fluid-cooled balun transformer 10.

For the purposes of explanation only, and not as a limitation to the present invention, hereinafter in the present disclosure the embodiment of the fluid-cooled balun transformer 10 for using to match balanced input to single-ended output has been discussed, i.e., the embodiment in which the first conductive element 3 functions as the primary winding of the fluid-cooled balun transformer 10, and the second conductive element 4 functions as the secondary winding of the fluid-cooled balun transformer 10. Referring again to FIG. 1, the fluid-cooled balun transformer 10 includes the cooling module 20. The cooling module 20 includes a first tubular member 21. The first tubular member is a hollow tube and includes a fluid inlet 22 to receive a coolant fluid (not shown) into the first tubular member 21, a flow channel 23 to conduct a flow of the coolant fluid within the first tubular member 21 after being received via the fluid inlet 22 and a fluid outlet 24 to release the coolant fluid from the first tubular member 21 after flowing through the flow channel 23. The flow channel 23 of the first tubular member 21 is arranged in thermal contact with the first conductive element 3. The first tubular member 21 may have a shape and size suitable for establishing an optimal thermal contact with the first conductive element 3. For example, as depicted in FIG. 1, the first tubular member 21 has a ‘C’ shaped structure formed from a rectangular parallelepiped bent to form the ‘V’ shape.

The flow channel 23 is positioned inside the first tubular member 21 and may have a shape similar to the shape of the first tubular member 21 as depicted in FIG. 1, or alternatively, the flow channel 23 positioned inside the first tubular member 21 may have a shape different from the shape of the first tubular member 21, as depicted in FIG. 5. FIG. 5 depicts the flow channel 23 that is a milled flow path 11 in the first tubular member 21. The flow channel 23 may be formed by machining, e.g., milling, or other any other suitable fabrication technique, e.g., laser sintering, to achieve a desired shape either the same as or different than the shape of the first tubular member 21.

As mentioned earlier, the flow channel 23 of the first tubular member 21 is in thermal contact with the first conductive element 3, i.e., in this exemplary embodiment of FIG. 1 in thermal contact with the primary winding. It may be noted that in the present disclosure the term ‘in thermal contact’ and similar phrases mean a direct physical or indirect, i.e., through other intermediate direct physical contacts between the flow channel 23 and the first conductive element 3 that allow transfer of thermal energy, primarily through conduction of heat, from the first conductive element 3 to the flow channel 23.

In one embodiment of the fluid-cooled balun transformer 10, the flow channel 23 of the first tubular member 21 is arranged in thermal contact with the first conductive element 3 by direct physical contact of the first tubular member 21 and the first conductive element 3, i.e., the thermal contact between the first conductive element 3 and the flow channel 23 of the first tubular member 21 is realized by direct physical contact of a surface (not shown) of the first conductive element 3 with a wall (not shown) or surface (now shown) of the first tubular member 21.

When the fluid-cooled balun transformer 10 is in use, and when a coolant fluid, i.e., a coolant liquid, is introduced into the fluid inlet 22 of the first tubular member 21, the coolant fluid flows through the flow channel 23 of the first tubular member 21 to the fluid outlet 24 of the first tubular member 21 and exits through the fluid outlet 24 of the first tubular member 21. The flow channel 23 is in thermal contact with the first conductive element 3. As a result, heat from the first conductive element 3 is conducted to the flow channel 23 of the first tubular member 21 and is thus received by the coolant fluid flowing in the flow channel 23 of the first tubular member 21 and is subsequently carried, along with the coolant fluid, off the fluid-cooled balun transformer 10 through the fluid outlet 24 of the first tubular member 21.

The fluid inlet 22 and the fluid outlet 24 may be positioned anywhere in the first tubular member 21. As an example, FIG. 1 shows the fluid inlet 22 and the fluid outlet 24 adjoining the region 8 and towards the first signal port 1, whereas FIG. 5 shows the fluid inlet 22 and the fluid outlet 24 adjoining the ground point 6.

In one embodiment of the fluid-cooled balun transformer 10, the flow channel 23 of the first tubular member 21 is shaped such that the coolant fluid flows in a laminar flow, whereas in an alternate embodiment of the fluid-cooled balun transformer 10, the flow channel 23 of the first tubular member 21 is shaped such that the coolant fluid flows in a turbulent manner. To conduct the flow of the coolant fluid turbulently, the flow channel has turbulence creating structures (not shown) in the flow path of the fluid coolant, such as protrusions (not shown) from an inner surface (not shown) of a wall (not shown) of the first tubular member 21 into the flow channel 23 of the first tubular member 21.

In another embodiment of the fluid-cooled balun transformer 10, the cooling module 20 includes a second tubular member (not shown). The second tubular member has similar features as explained for the first tubular member 21 in reference to FIGS. 4 and 5, the difference being that the second tubular member is arranged in thermal contact with the second conductive element 4. All the features of the second tubular member, such as the fluid inlet of the second tubular member configured to receive a coolant fluid into the second tubular member, a flow channel of the second tubular member configured to conduct a flow of coolant fluid within the second tubular member and a fluid outlet of the second tubular member configured to release the coolant fluid from the second tubular member, all are similar to the comparable features of the first tubular member 21 and can be easily appreciated by one having skill in the art. The cooling provided by the second tubular member to the second conductive element 4 is comparable for explanation purposes to the cooling provided by the first tubular member 21 to the first conductive element 3 and thus not explained herein in details for sake of brevity.

Thus, in at least one embodiment (not shown) of the present invention, the fluid-cooled balun transformer 10 includes the first tubular member 21 for cooling the first conductive element 3 and the second tubular member for cooling the second conductive element 4. In another embodiment (not shown) of the fluid-cooled balun transformer 10, the flow channel 23 of the first tubular member 21 may be fluidly unlinked to or not connected with the flow channel of the second tubular member, whereas in an alternate embodiment (not shown) of the fluid-cooled balun transformer 10, the flow channel 23 of the first tubular member 21 may be fluidly linked to or connected with the flow channel of the second tubular member.

While the present technique has been described in detail with reference to certain embodiments, it should be appreciated that the present technique is not limited to those precise embodiments. Rather, in view of the present disclosure which describes exemplary modes for practicing the invention, many modifications and variations would present themselves, to those skilled in the art without departing from the scope and spirit of this invention. The scope of the invention is, therefore, indicated by the following claims rather than by the foregoing description. All changes, modifications, and variations coming within the meaning and range of equivalency of the claims are to be considered within their scope.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A fluid-cooled balanced to unbalanced (balun) transformer comprising:
a substrate plate having a first face and a second face which are opposite to each other;
a first conductive element arranged on the first face of the substrate plate;
a second conductive element arranged on the second face of the substrate plate, the second conductive element being transformingly coupled to the first conductive element and being electrically isolated therefrom;
a first signal port electrically connected to the first conductive element;
a second signal port electrically connected to the second conductive element; and
a cooling module having a first tubular member comprising a fluid inlet configured to receive a coolant fluid into the first tubular member, a flow channel configured to conduct a flow of coolant fluid in the first tubular member and a fluid outlet configured to release the coolant fluid from the first tubular member;
wherein the flow channel of the first tubular member is arranged in thermal contact with the first conductive element.

17. The fluid-cooled balun transformer according to claim 16, wherein at least a part of the first conductive element is printed on the first face of the substrate plate.

18. The fluid-cooled balun transformer according to claim 16, wherein at least a part of the second conductive element is printed on the second face the substrate plate.

19. The fluid-cooled balun transformer according to claim 17, wherein at least a part of the second conductive element is printed on the second face of the substrate plate.

20. The fluid-cooled balun transformer according to claim 16, wherein the flow channel of the first tubular member is arranged in thermal contact with the first conductive element by direct physical contact of the first tubular member and the first conductive element.

21. The fluid-cooled balun transformer according to claim 16, wherein the first conductive element comprises a ground point for grounding the first conductive element; and
wherein at least one of the fluid inlet and the fluid outlet of the first tubular member is positioned proximate to the ground point of the first conductive element.

22. The fluid-cooled balun transformer according to claim 16, wherein the flow channel of the first tubular member is configured to conduct a flow of the coolant fluid turbulently.

23. The fluid-cooled balun transformer according to claim 16, wherein a shape of the flow channel of the first tubular member is different from a shape of the first tubular member.

24. The fluid-cooled balun transformer according to claim 16, wherein the first signal port is a balanced signal port and the second signal port is a single-ended signal port.

25. The fluid-cooled balun transformer according to claim 16, wherein the first signal port is a single-ended signal port and the second signal port is a balanced signal port.

26. The fluid-cooled balun transformer according to claim 24, wherein the cooling module comprises a second tubular member, the second tubular member having a fluid inlet configured to receive a coolant fluid into the second tubular member, a flow channel configured to conduct a flow of the coolant fluid in the second tubular member and a fluid outlet configured to release the coolant fluid from the second tubular member; and
wherein the flow channel of the second tubular member is arranged in thermal contact with the second conductive element.

27. The fluid-cooled balun transformer according to claim 25, wherein the cooling module comprises a second tubular member, the second tubular member having a fluid inlet configured to receive a coolant fluid into the second tubular member, a flow channel configured to conduct a flow of the coolant fluid in the second tubular member and a fluid outlet configured to release the coolant fluid from the second tubular member; and
wherein the flow channel of the second tubular member is arranged in thermal contact with the second conductive element.

28. The fluid-cooled balun transformer according to claim 26, wherein the flow channel of the second tubular member is arranged in thermal contact with the second conductive element by direct physical contact of the second tubular member with the second conductive element.

29. The fluid-cooled balun transformer according to claim 26, wherein the second conductive element comprises a ground point for grounding the second conductive element; and
wherein at least one of the fluid inlet and the fluid outlet of the second tubular member is positioned proximate to the ground point of the second conductive element.

30. The fluid-cooled balun transformer according to claim 28, wherein the second conductive element comprises a ground point for grounding the second conductive element; and
wherein at least one of the fluid inlet and the fluid outlet of the second tubular member is positioned proximate to the ground point of the second conductive element.

31. The fluid-cooled balun transformer according to claim 26, wherein the flow channel of the second tubular member is configured to conduct the flow of the coolant fluid turbulently.

32. The fluid-cooled balun transformer according to claim 28, wherein the flow channel of the second tubular member is configured to conduct the flow of the coolant fluid turbulently.

33. The fluid-cooled balun transformer according to claim 29, wherein the flow channel of the second tubular member is configured to conduct the flow of the coolant fluid turbulently.

34. The fluid-cooled balun transformer according to claim 26, wherein a shape of the flow channel of the second tubular member is different from a shape of the second tubular member.

35. The fluid-cooled balun transformer according to claim 26, wherein the flow channel of the first tubular member is fluidly connected to the flow channel of the second tubular member.
